(19) United States
(12) Patent Application Publication
(10) Pub. No.: US 2026/0131665 A1
(43) Pub. Date: May 14, 2026

(54) SOFT CLAMP CIRCUIT FOR MOTOR DRIVER SUPPLY RAIL WITH REVERSE POLARITY PROTECTION

(71) Applicant: GM GLOBAL TECHNOLOGY OPERATIONS LLC, Detroit, MI (US)

(72) Inventors: Peter Rolf IRGENS, Novi, MI (US); Nicholas Logan HARVELL, Brownstown, MI (US); S.M. Nayeem HASAN, Novi, MI (US)

(21) Appl. No.: 18/944,170

(22) Filed: Nov. 12, 2024

(51) Int. Cl. B60L 15/20; B60L 3/00; B60L 50/52; B60R 16/033; H03K 17/0812

(52) U.S. Cl. CPC B60L 15/20; B60L 3/0046; B60L 50/52; B60R 16/033; H03K 17/08122

(57) ABSTRACT

A motor control system includes a motor controller and a switch arranged between a battery and a conductor. The motor controller closes the switch when the battery supplies a battery voltage and opens the switch when the battery is not supplying the battery voltage. A clamp circuit is connected to the conductor. A capacitor is connected to the conductor. An H-bridge controller is configured to selectively control a plurality of switches to supply alternating current to a motor in response to a command from the motor controller; sense a voltage on the conductor when the battery is not supplying power to the motor controller; when the voltage on the conductor is greater than a first predetermined voltage threshold, close at least two of the plurality of switches; and when the voltage on the conductor is less than a second predetermined voltage threshold, open at least two of the switches.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure relates to motor control systems, and more particularly to a soft clamp circuit for a motor driver supply rail with reverse polarity protection.

Vehicles may include a component such as a lift gate that is powered by a motor. During operation, a controller supplies power from the battery to a motor controller that controls switches that supply alternating current to the motor.

### SUMMARY

A motor control system includes a motor controller and a switch arranged between a battery and a conductor. The motor controller is configured to close the switch when the battery supplies a battery voltage on the conductor and open the switch when the battery is not supplying the battery voltage on the conductor. A clamp circuit is connected to the conductor. A capacitor is connected to the conductor. An H-bridge controller is configured to selectively control a plurality of switches to supply alternating current to a motor in response to a command from the motor controller; sense a voltage on the conductor when the battery is not supplying power to the motor controller; when the voltage on the conductor is greater than a first predetermined voltage threshold, close at least two of the plurality of switches; and when the voltage on the conductor is less than a second predetermined voltage threshold, open at least two of the switches.

In other features, the second predetermined voltage threshold is less than the first predetermined voltage threshold and greater than the battery voltage. The clamp circuit includes a resistor and a Zener diode. The Zener diode has a Zener voltage that is less than the second predetermined voltage threshold and greater than the battery voltage.

The plurality of switches include a first switch including a first terminal connected to the conductor; a second switch including a first terminal connected to a second terminal of the first switch and first terminal of the motor and a second terminal connected to ground; a third switch including a first terminal connected to the conductor; and a fourth switch including a first terminal connected to a second terminal of the third switch and a second terminal of the motor and a second terminal connected to ground.

In other features, the at least two of the plurality of switches includes the second switch and the fourth switch. The at least two of the plurality of switches includes the first switch and the third switch. The first predetermined voltage threshold is in a range from 29 volts to 31 volts. The second predetermined voltage threshold is in a range from 26 volts to 28 volts. The Zener voltage is in a range from 19 to 21 volts and the battery voltage is in a range from 10 to 17 volts.

A motor control system includes a motor controller and a switch arranged between a battery and a conductor. The motor controller is configured to close the switch when the battery supplies battery voltage on the conductor and open the switch when the battery is not supplying the battery voltage on the conductor. A clamp circuit is connected to the conductor and including a resistor connected in series with a Zener diode. A capacitor is connected to the conductor. An H-bridge controller is configured to selectively control a plurality of switches to supply alternating current to a motor in response to a command from the motor controller; sense a voltage on the conductor when the battery is not supplying power to the motor controller; when the voltage on the conductor is greater than a first predetermined voltage threshold, close at least two of the plurality of switches; and when the voltage on the conductor is less than a second predetermined voltage threshold, open at least two of the switches. The second predetermined voltage threshold is less than the first predetermined voltage threshold and greater than the battery voltage. The Zener diode has a Zener voltage that is less than the second predetermined voltage threshold and greater than the battery voltage.

In other features, the plurality of switches include a first switch including a first terminal connected to the conductor; a second switch including a first terminal connected to a second terminal of the first switch and a first terminal of the motor and a second terminal connected to ground; a third switch including a first terminal connected to the conductor; and a fourth switch including a first terminal connected to a second terminal of the third switch and a second terminal of the motor and a second terminal connected to ground.

In other features, the at least two of the plurality of switches includes the second switch and the fourth switch. The at least two of the plurality of switches includes the first switch and the third switch. The first predetermined voltage threshold is in a range from 29 volts to 31 volts. The second predetermined voltage threshold is in a range from 26 volts to 28 volts. The Zener voltage is in a range from 19 to 21 volts and the battery voltage is in a range from 10 to 17 volts.

A vehicle comprises a lift gate, a motor configured to move the lift gate, and a motor controller. A switch is arranged between a battery and a conductor. The motor controller is configured to close the switch when the battery supplies battery voltage on the conductor and open the switch when the battery is not supplying the battery voltage on the conductor. A clamp circuit is connected to the conductor and includes a resistor connected in series with a Zener diode. A capacitor is connected to the conductor. An H-bridge controller is configured to selectively control a plurality of switches to supply alternating current to the motor in response to a command from the motor controller; sense a voltage on the conductor when the battery is not supplying power to the motor controller; when the voltage on the conductor is greater than a first predetermined voltage threshold, close at least two of the plurality of switches; and when the voltage on the conductor is less than a second predetermined voltage threshold, open at least two of the switches. The second predetermined voltage threshold is less than the first predetermined voltage threshold and greater than the battery voltage. The Zener diode has a Zener voltage that is less than the second predetermined voltage threshold and greater than the battery voltage.

In other features, the plurality of switches include a first switch including a first terminal connected to the conductor; a second switch including a first terminal connected to a second terminal of the first switch and a first terminal of the motor and a second terminal connected to ground; a third switch including a first terminal connected to the conductor; and a fourth switch including a first terminal connected to a second terminal of the third switch and a second terminal of the motor and a second terminal connected to ground.

In other features, the at least two of the plurality of switches includes the second switch and the fourth switch.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1A is functional block diagram and electrical schematic of a motor control system for a motor that actuates a component such as a liftgate of a vehicle;

FIG. 1B is functional block diagram and electrical schematic of the control system of FIG. 1A showing back electromotive force (EMF) and charging of a bulk capacitor;

FIG. 2 is functional block diagram and electrical schematic of an example of a motor control system including a soft clap circuit according to the present disclosure;

FIG. 3 is a functional block diagram and electrical schematic of the motor control system of FIG. 2 showing back electromotive force (EMF) that may occur when the motor is manually rotated when the battery is disconnected;

FIG. 4 is a functional block diagram and electrical schematic of the motor control system of FIG. 2 showing operation of the H-Bridge controller and soft clamp circuit according to the present disclosure; and

FIG. 5 is a flowchart of an example of a method for operating the H-bridge controller according to the present disclosure.

In the drawings, reference numbers may be reused to identify similar and/or identical elements.

### DETAILED DESCRIPTION

Vehicles may include a component such as a lift gate, sliding door, or other component that is powered by a motor. During operation, power is supplied from a battery to a motor control system to controls states of a plurality of switches that supply alternating current to the motor. During assembly or service, there are situations when the battery is disconnected and the motor control system is not powered by the battery. Problems may arise when power is not supplied to the motor control system and the motor of the component is manually rotated and generates back electromotive force (EMF). The back EMF may cause voltage greater than 30V to be stored on a bulk capacitor in the motor control system, which may harm other components of the motor control system.

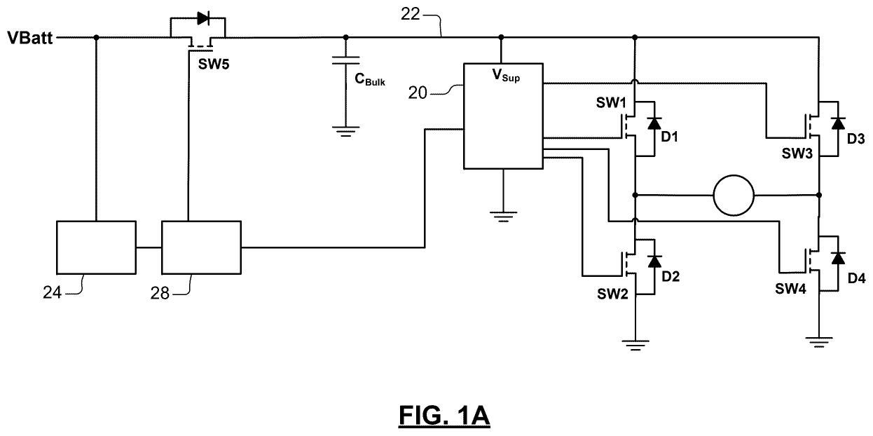

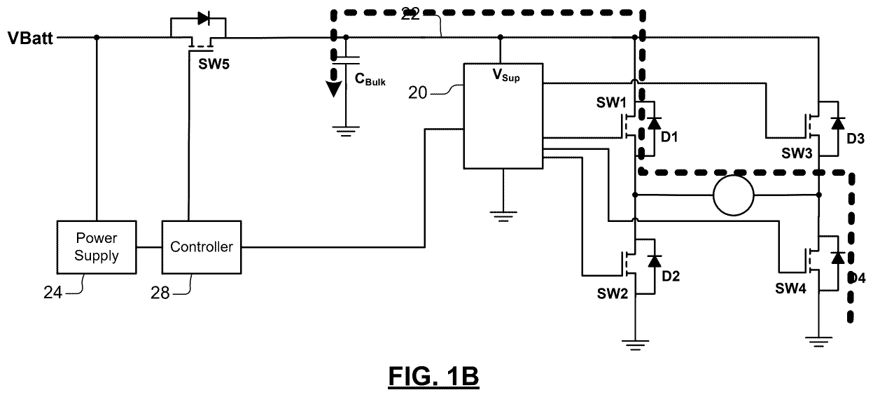

Referring now to FIGS. 1A and 1B, a motor control system includes an H-bridge driver 20 configured to control operation of a motor M. More particularly, the H-bridge driver 20 controls states of switches SW₁, SW₂, SW₃, and SW₄ to supply alternating current across the input terminals of the motor M.

The H-bridge driver 20 is connected to control terminals of the switches SW₁, SW₂, SW₃, and SW₄. The switches SW₁ and SW₂ and SW₃ and SW₄ are respectively connected in series between a conductor 22 (or a voltage supply rail or Vₛᵤₚ) and ground. First terminals of the switches SW₁ and SW₃ are connected to the conductor 22. Second terminals of the switches SW₁ and SW₂ are connected to first terminals of the switches SW₃ and SW₄. Second terminals of the switches SW₃ and SW₄ are connected to ground. The switches SW₁, SW₂, SW₃, and SW₄ include body diodes D₁, D₂, D₃, and D₄ connected across the first and second terminals of the switches SW₁, SW₂, SW₃, and SW₄.

Input terminals of the motor M are connected to nodes between the second terminals of the switches SW₁ and SW₂ and the first terminals of the switches SW₃ and SW₄. During operation of the motor M, the H-bridge driver 20 turns on switches SW₁ and SW₄ while switches SW₂ and SW₃ are off (and then vice versa) to supply alternating current to the motor M.

During vehicle assembly and/or servicing, the battery of the vehicle may be disconnected (e.g., no power is provided to the controller 28). When the controller 28 is not powered, the switch SW₅ is normally open (to prevent current from back-feeding from the conductor 22 (or supply rail (Vₛᵤₚ)) to the system supply input).

In FIG. 1B, when the motor M is manually rotated while the battery is disconnected, the motor M generates back-electromotive force (EMF) (e.g., as shown by dotted line). Voltage on the conductor 22 rises steadily (e.g., to more than 30V) and the bulk capacitor C_{Bulk} is charged. The stored energy may damage the controller 28 or other components if the motor back-EMF is not limited.

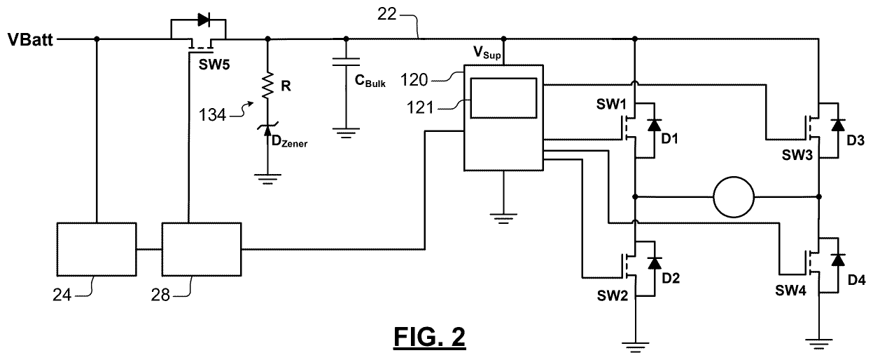

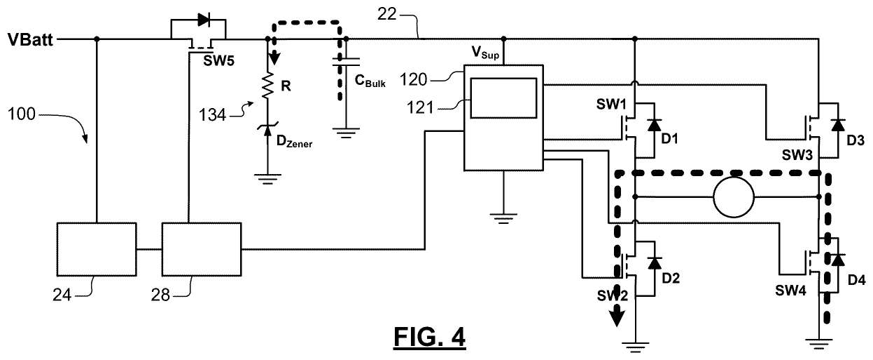

Referring now to FIGS. 2 to 4, an H-Bridge controller 120 acts as a driver as described above to selectively supply current in opposite directions across the motor M by changing states of switches SW₁, SW₂, SW₃, and SW₄ during normal operation. The bulk capacitor C_{bulk} is connected to the conductor 22. The H-Bridge controller 120 includes a motor braking module 121 that senses the voltage of the supply rail Vₛᵤₚ, selectively shorts terminals of the motor M when Vₛᵤₚ is greater than a first predetermined voltage threshold V_{TH1}, and then selectively stops shorting terminals of the motor M when Vₛᵤₚ is less than a second predetermined voltage threshold V_{TH2} as will be described further below.

A soft clamp circuit 134 includes a resistor R and a Zener diode D_{Zener} connected in series between the conductor 22 and ground. The power supply 24 is connected to V_{BATT}. The controller 28 is connected to the power supply 24, the H-Bridge controller 120, and a control terminal of the switch SW₅ (connected between V_{BATT} and the conductor 22). The controller 28 is configured to control the H-Bridge controller 120 and the switch SW₅.

The soft clamp circuit 134 is configured to discharge the bulk capacitor C_{bulk} when the rail voltage Vₛᵤₚ is greater than the first predetermined voltage threshold (until Vₛᵤₚ falls below the second predetermined threshold). When the controller 28 is powered, the switch SW₅ is closed. When the controller 28 is not powered, the switch SW₅ is normally open to prevent current from back-feeding from the conductor 22 (or supply rail (Vₛᵤₚ)) to the system supply input.

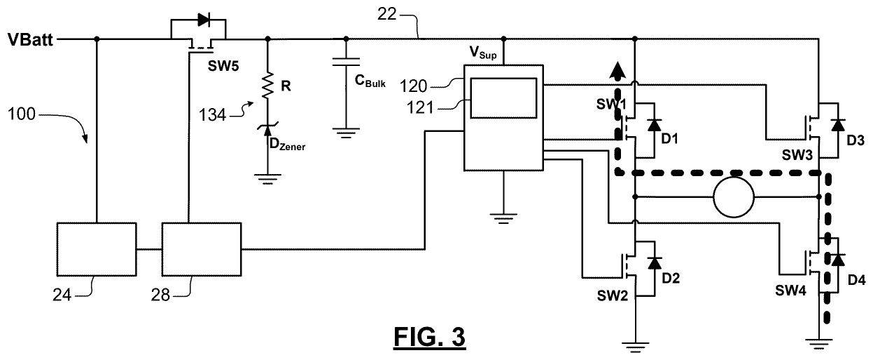

In FIG. 3, the switches SW₁, SW₂, SW₃, and SW₄ of the H-Bridge controller 120 are off (when V_{BATT} is not supplied). When the motor M is manually rotated, the motor M generates back-EMF. Since V_{BATT} is not supplied to the power supply 24, the controller 28 does not provide power to the H-Bridge controller 120 or the switch SW₅.

Despite not being powered by the power supply 24 and the controller 28, the motor brake module 121 of the H-Bridge controller 120 is configured to sense when the supply rail voltage (Vₛᵤₚ) rises above the first predetermined voltage threshold (e.g., a dynamic braking enable threshold) (e.g., 30V). The first predetermined voltage threshold is greater than V_{BATT} (e.g., 16V).

Back-EMF flows through body diodes D₄ and D₁ or D₂ and D₃ to charge the bulk capacitor C_{Bulk}. When the first predetermined voltage threshold V_{TH1} is sensed, the H-Bridge controller 120 switches ON either SW₂ and SW₄ (or SW₁ and SW₃) to short terminals of the motor M (to ground or Vₛᵤₚ) and clamp the back-EMF across the motor M. The H-Bridge controller 120 is configured to turn off switches SW₂ and SW₄ (or SW₁ and SW₃) when the supply rail voltage (Vₛᵤₚ) falls below a second predetermined voltage (e.g., a dynamic braking disable threshold) (e.g., 27V).

The soft clamp circuit 134 dissipates voltage stored on the bulk capacitor C_{bulk} when the switch SW₅ is OFF and the supply voltage to the H-Bridge controller 120 exceeds the Zener voltage of the Zener diode D_{Zener}. In some examples, the bulk capacitor C_{bulk} is sized to minimize braking time, provide smooth operation, and avoid electromagnetic compatibility (EMC) issues.

The magnitude of current draw is limited by the resistor R. The Zener voltage of D_{Zener} is selected below the second predetermined voltage threshold V_{TH2} of the H-Bridge controller 120 such that the soft clamp circuit 134 draws current from the supply rail (Vₛᵤₚ) (controlled by the bulk capacitor C_{bulk}) until the supply rail (Vₛᵤₚ) voltage falls below the second predetermined voltage threshold V_{TH2}.

In some examples, the first predetermined voltage threshold V_{TH1} is greater than the second predetermined voltage threshold V_{TH2}. In some examples the first predetermined voltage threshold V_{TH1} is in a range from 29 to 31 volts (V) (e.g., 30V). In some examples, the second predetermined voltage threshold V_{TH2} is less than the first predetermined voltage and greater than V_{BATT}. In some examples the second predetermined voltage threshold V_{TH2} is in a range from 26 to 28 volts (V) (e.g., 27V).

In some examples, V_{BATT} is the normal operation battery voltage and is in a range from 10V to 17V (˜16V). In some examples, the Zener voltage is greater than V_{BATT} and less than the second predetermined voltage threshold V_{TH2}. In some examples, the Zener voltage is in a range from 19 to 21V (e.g., 20V).

The capacitance value of the bulk capacitor C_{Bulk} is selected to handle motor transients. A discharge time of the soft clamp circuit corresponds to the time to discharge the supply voltage Vₛᵤₚ from the first predetermined voltage threshold V_{TH1} to the second predetermined voltage threshold V_{TH2}. The discharge time is equal to—

$$R * {C}_{Bulk} * ln ( \frac{Second . pred . volt . thr - Zener volt}{First . pred . volt . thr - Zener volt} ) .$$

In some examples, the discharge time is set to a value less than the maximum motor braking time. If discharge time is too long, the resistance value of the resistor R and/or the capacitance value of the bulk capacitor C_{Bulk} can be reduced.

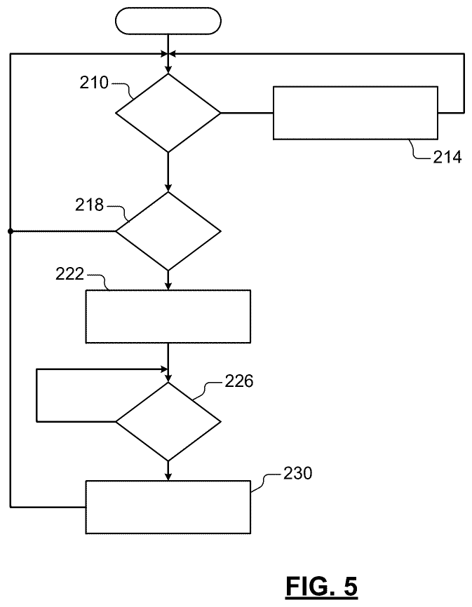

Referring now to FIG. 5, operation of the H-Bridge driver is shown. At 210, the H-Bridge controller 120 determines whether the controller 28 is powered. If true, the H-Bridge controller 120 controls the switches SW₁, SW₂, SW₃, and SW₄ to control the motor based on the controller command at 214. If 210 is false, the H-Bridge controller 120 determines whether Vₛᵤₚ is greater than the first predetermined voltage threshold (V_{TH1}) at 218. If 218 is false, the method returns to 210. If 218 is true, the method closes the switches (S₂ and S₄) to ground the terminals of the motor M at 222 (or closes the switches (S₁ and S₃) to short the terminals of the motor M to Vₛᵤₚ). At 226, the H-bridge driver determines whether Vₛᵤₚ is less than the second predetermined voltage threshold (V_{TH2}). If 226 is false, the method returns to 226. If 226 is true, the method opens the switches (S₂ and S₄) (or opens the switches (S₁ and S₃)) and returns to 210.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

In this application, including the definitions below, the term “module” or the term “controller” may be replaced with the term “circuit.” The term “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components that provide the described functionality; or a combination of some or all of the above, such as in a system-on-chip.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

The term code, as used above, may include software, firmware, and/or microcode, and may refer to programs, routines, functions, classes, data structures, and/or objects. The term shared processor circuit encompasses a single processor circuit that executes some or all code from multiple modules. The term group processor circuit encompasses a processor circuit that, in combination with additional processor circuits, executes some or all code from one or more modules. References to multiple processor circuits encompass multiple processor circuits on discrete dies, multiple processor circuits on a single die, multiple cores of a single processor circuit, multiple threads of a single processor circuit, or a combination of the above. The term shared memory circuit encompasses a single memory circuit that stores some or all code from multiple modules. The term group memory circuit encompasses a memory circuit that, in combination with additional memories, stores some or all code from one or more modules.

The term memory circuit is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only memory circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general purpose computer to execute one or more particular functions embodied in computer programs. The functional blocks, flowchart components, and other elements described above serve as software specifications, which can be translated into the computer programs by the routine work of a skilled technician or programmer.

The computer programs include processor-executable instructions that are stored on at least one non-transitory, tangible computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

The computer programs may include: (i) descriptive text to be parsed, such as HTML (hypertext markup language), XML (extensible markup language), or JSON (JavaScript Object Notation) (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C#, Objective-C, Swift, Haskell, Go, SQL, R, Lisp, Java®, Fortran, Perl, Pascal, Curl, OCaml, Javascript®, HTML5 (Hypertext Markup Language 5th revision), Ada, ASP (Active Server Pages), PHP (PHP: Hypertext Preprocessor), Scala, Eiffel, Smalltalk, Erlang, Ruby, Flash®, Visual Basic®, Lua, MATLAB, SIMULINK, and Python®.

1. A motor control system, comprising:
a motor controller;
a switch arranged between a battery and a conductor,
wherein the motor controller is configured to close the switch when the battery supplies a battery voltage on the conductor and open the switch when the battery is not supplying the battery voltage on the conductor;
a clamp circuit connected to the conductor;
a capacitor connected to the conductor; and
an H-bridge controller configured to:
selectively control a plurality of switches to supply alternating current to a motor in response to a command from the motor controller;
sense a voltage on the conductor when the battery is not supplying power to the motor controller;
when the voltage on the conductor is greater than a first predetermined voltage threshold, close at least two of the plurality of switches; and
when the voltage on the conductor is less than a second predetermined voltage threshold, open at least two of the switches.

2. The motor control system of claim 1, wherein the second predetermined voltage threshold is less than the first predetermined voltage threshold and greater than the battery voltage.

3. The motor control system of claim 1, wherein the clamp circuit includes a resistor and a Zener diode.

4. The motor control system of claim 3, wherein the Zener diode has a Zener voltage that is less than the second predetermined voltage threshold and greater than the battery voltage.

5. The motor control system of claim 1, wherein the plurality of switches include:
a first switch including a first terminal connected to the conductor;
a second switch including a first terminal connected to a second terminal of the first switch and a first terminal of the motor and a second terminal connected to ground;
a third switch including a first terminal connected to the conductor;
a fourth switch including a first terminal connected to a second terminal of the third switch and a second terminal of the motor and a second terminal connected to ground.

6. The motor control system of claim 5, wherein the at least two of the plurality of switches includes the second switch and the fourth switch.

7. The motor control system of claim 5, wherein the at least two of the plurality of switches includes the first switch and the third switch.

8. The motor control system of claim 2, wherein the first predetermined voltage threshold is in a range from 29 volts to 31 volts.

9. The motor control system of claim 2, wherein the second predetermined voltage threshold is in a range from 26 volts to 28 volts.

10. The motor control system of claim 4, wherein the Zener voltage is in a range from 19 to 21 volts and the battery voltage is in a range from 10 to 17 volts.

11. A motor control system, comprising:
a motor controller;
a switch arranged between a battery and a conductor,
wherein the motor controller is configured to close the switch when the battery supplies battery voltage on the conductor and open the switch when the battery is not supplying the battery voltage on the conductor;
a clamp circuit connected to the conductor and including a resistor connected in series with a Zener diode;
a capacitor connected to the conductor; and
an H-bridge controller configured to:
selectively control a plurality of switches to supply alternating current to a motor in response to a command from the motor controller;
sense a voltage on the conductor when the battery is not supplying power to the motor controller;
when the voltage on the conductor is greater than a first predetermined voltage threshold, close at least two of the plurality of switches; and
when the voltage on the conductor is less than a second predetermined voltage threshold, open at least two of the switches,
wherein the second predetermined voltage threshold is less than the first predetermined voltage threshold and greater than the battery voltage, and
wherein the Zener diode has a Zener voltage that is less than the second predetermined voltage threshold and greater than the battery voltage.

12. The motor control system of claim 11, wherein the plurality of switches include:
a first switch including a first terminal connected to the conductor;
a second switch including a first terminal connected to a second terminal of the first switch and a first terminal of the motor and a second terminal connected to ground;
a third switch including a first terminal connected to the conductor;
a fourth switch including a first terminal connected to a second terminal of the third switch and a second terminal of the motor and a second terminal connected to ground.

13. The motor control system of claim 12, wherein the at least two of the plurality of switches includes the second switch and the fourth switch.

14. The motor control system of claim 12, wherein the at least two of the plurality of switches includes the first switch and the third switch.

15. The motor control system of claim 11, wherein the first predetermined voltage threshold is in a range from 29 volts to 31 volts.

16. The motor control system of claim 11, wherein the second predetermined voltage threshold is in a range from 26 volts to 28 volts.

17. The motor control system of claim 11, wherein the Zener voltage is in a range from 19 to 21 volts and the battery voltage is in a range from 10 to 17 volts.

18. A vehicle comprising:
a lift gate;
a motor configured to move the lift gate;
a motor controller;
a switch arranged between a battery and a conductor,
wherein the motor controller is configured to close the switch when the battery supplies battery voltage on the conductor and open the switch when the battery is not supplying the battery voltage on the conductor;
a clamp circuit connected to the conductor and including a resistor connected in series with a Zener diode;
a capacitor connected to the conductor; and
an H-bridge controller configured to:
selectively control a plurality of switches to supply alternating current to the motor in response to a command from the motor controller;
sense a voltage on the conductor when the battery is not supplying power to the motor controller;
when the voltage on the conductor is greater than a first predetermined voltage threshold, close at least two of the plurality of switches; and
when the voltage on the conductor is less than a second predetermined voltage threshold, open at least two of the switches,
wherein the second predetermined voltage threshold is less than the first predetermined voltage threshold and greater than the battery voltage, and
wherein the Zener diode has a Zener voltage that is less than the second predetermined voltage threshold and greater than the battery voltage.

19. The vehicle of claim 18, wherein the plurality of switches include:
a first switch including a first terminal connected to the conductor;
a second switch including a first terminal connected to a second terminal of the first switch and a first terminal of the motor and a second terminal connected to ground;
a third switch including a first terminal connected to the conductor;
a fourth switch including a first terminal connected to a second terminal of the third switch and a second terminal of the motor and a second terminal connected to ground.

20. The vehicle of claim 19, wherein the at least two of the plurality of switches includes the second switch and the fourth switch.
